(19) United States
(12) Patent Application Publication
(10) Pub. No.: US 2026/0017419 A1
(43) Pub. Date: Jan. 15, 2026

(54) SYSTEM AND METHODS FOR GENERATING SEMANTICALLY STRUCTURED THREE-DIMENSIONAL SCENE REPRESENTATIONS FROM UNSTRUCTURED MULTIMEDIA INPUT DATA

(71) Applicant: HL Acquisition, Inc. dba Hosta AI, Cambridge, MA (US)

(72) Inventors: Rachelle Villalon, Cambridge, MA (US); Ryan Borucki, Cambridge, MA (US); John D'Alessandro, Cambridge, MA (US); Audrey Routt, Cambridge, MA (US)

(21) Appl. No.: 19/269,457

(22) Filed: Jul. 15, 2025

Related U.S. Application Data
(60) Provisional application No. 63/671,663, filed on Jul. 15, 2024.
(60) Provisional application No. 63/720,576, filed on Nov. 14, 2024.

(51) Int. Cl. G06F 30/12; G06T 17/10; G06V 10/764; G06V 10/82

(52) U.S. Cl. CPC G06F 30/12; G06T 17/10; G06V 10/764; G06V 10/82

(57) ABSTRACT

A system for generating semantically structured three-dimensional scene representations from unstructured multimedia input data, comprising: an input data receiver configured to receive unstructured, multimedia input; a two dimensional detector configured to receive the unstructured, multimedia input data and to execute computer vision logic on the received unstructured, multimedia input data to detect one or more building materials, one or more damage patterns, one or more architectural elements, and to extract dimensional information; a three-dimensional reconstruction engine configured to reconstruct a metrically accurate three-dimensional model of the physical interior space from the input data; a metadata generation engine configured to generate structured metadata from outputs of the two dimensional detector and the three-dimensional reconstruction engine; and a rule-based converter engine configured to process the structured metadata in accordance with a set of externally defined, carrier-specific rules to generate one or more claims estimate reports.

### CLAIM OF PRIORITY

This application claims priority under 35 U.S.C. § 119 (c) to U.S. Patent Application Ser. No. 63/671,663, filed on Jul. 15, 2024, and to U.S. Patent Application Ser. No. 63/720,576, filed on Nov. 14, 2024, the entire contents of each of which are hereby incorporated by reference.

### TECHNICAL FIELD

The techniques described herein pertain to using computer vision in the generation of two dimensional (2D) and three dimensional (3D) images.

### BACKGROUND

The insurance industry faces significant challenges in processing property damage claims efficiently and accurately. Traditional claim assessment approaches rely heavily on manual human analysis, which presents critical limitations that impact both insurance carriers and policyholders. Currently, when property damage claims are submitted to insurance companies for processing, a human adjuster, either in the field or at a desk, must analyze the claims using site visits, images, videos, and other input information to produce a comprehensive claims estimate report. This manual process requires determining multiple complex factors including manual labor hours, types of labor involved based on the specific property damage, architectural building properties affected such as material grades, structures, contents, size of damage, size of architectural element effects, damage severity, and associated costs.

The creation of these reports varies significantly across third-party insurance carriers due to varying carrier guidelines, software platforms, and estimation standards. The process typically involves creating floor plans derived from hand-drawn or digital sketches and measurements, all of which contributes to a claims estimation process that is inherently time-consuming, costly, and error-prone.

These inefficiencies in the current system result in delayed claim processing, inconsistent assessments between adjusters, increased operational costs for insurance carriers, and frustrated policyholders awaiting claim resolution. Additionally, the manual nature of the process introduces subjective variability that can lead to disputes and reduced accuracy in damage assessment. There exists a need in the art for an automated system that can process multiple types of input data to generate accurate, consistent, and rapid building damage assessment while accommodating different carrier guidelines and standards.

### SUMMARY

The techniques described herein provide a comprehensive automated system for precise building damage assessments that addresses the limitations of current manual and existing automated systems for claim processing methods. The system transforms the traditional claims assessment workflow through processing of various input data and automated generation of detailed claim estimates. The solution comprises of three main integrated stages: processing of input data, input data processing and conversion, and output generation of claims estimate reports from a converter engine that appropriately generates guidelines by carrier based on the system's metadata.

In the first stage, the system accepts diverse input data types including, images, videos, 3D data, point clouds, voice recordings, drawings, scanned assets, and other multimedia input data uploaded by users to the system. In the second stage, the system processes the input data through a 2D and 3D computer vision and machine learning service to determine structures, sizes, content, measurements, square footages, volume, and other characteristics of areas of interest for estimating claims from the input data.

In the third stage, the system generates metadata for a converter engine that contains one or more specialized modules for reasoning, analyzing, and utilizing other relevant data sources in conjunction with one or many third-party carrier guidelines to produce accurate claims estimate reports. The reports can be generated automatically in both two-2D and 3D outputs. Additionally, the outputs from the converter engine can be inserted into a comparator database available via Application Programming Interface (API) for comparing claims estimates across different regions, time periods, properties, change detections, and other comparisons of interest with respect to the property.

A system for generating semantically structured three-dimensional scene representations from unstructured multimedia input data, comprising: an input data receiver configured to receive unstructured, multimedia input data including one or more: images, videos, three-dimensional data, point cloud data, voice recordings, drawings, or scanned assets associated with a physical interior space; a two dimensional detector configured to receive the unstructured, multimedia input data and to execute computer vision logic on the received unstructured, multimedia input data to detect one or more building materials, one or more damage patterns, one or more architectural elements, and to extract dimensional information; a three-dimensional reconstruction engine configured to reconstruct a metrically accurate three-dimensional model of the physical interior space from the input data; a metadata generation engine configured to generate structured metadata from outputs of the two dimensional detector and the three-dimensional reconstruction engine, the structured metadata including one or more quantitative measurements, one or more material classifications, one or more structural damage assessments, dimensional data, and one or more confidence scores; and a rule-based converter engine configured to process the structured metadata in accordance with a set of externally defined, carrier-specific rules to generate one or more claims estimate reports, the rule-based converter engine comprising an output generation component configured to produce reports, two-dimensional data, three-dimensional data, and supporting documentation formatted according to the carrier-specific rules.

In some examples, the system includes a rules engine for insurance claims processing comprising: a rule management module configured to maintain carrier-specific rule sheets defining trigger conditions based on damage location, material types, and damage characteristics; a lookup module configured to access structured rule sheets containing condition parameters including supercategory classifications, material specifications, room type specifications, application notifiers with conditional logic statements, action matrices with dynamic categories and calculation instructions, and line item specifications with detailed action descriptions; an evaluation engine configured to process complex conditional logic through structured enumeration systems and dynamic string generation, the evaluation engine maintaining extensive material taxonomies and processing damage in relation to specific structural contexts; a rule selection component configured to generate dynamic evaluation strings through a BaseModel architecture that processes inclusion and exclusion criteria for parent structures, materials, damage subcategories, and room types; and a rule application component configured to construct complex boolean expressions combining multiple criteria with AND logic operators and execute carrier-specific guidelines based on the generated evaluation strings.

In some examples, the rule management module maintains tabbed interfaces enabling selection between multiple rule configurations for different damage scenarios including flooring removal, bathroom floor replacement, wood floor replacement, and carpet repair and replacement. The evaluation engine maintains material taxonomies including acoustic ceiling tiles, brick, carpet, concrete, fabric, gypsum, gypsum popcorn, laminate, marble, stone, tile variations including standard tile, tile_shower, and tile_tub, vinyl, wallpaper, and wood classifications. The evaluation engine processes damage classifications including carpet_removed, ceiling_material_removed, delamination, deteriorated surfaces, drywall_removed, exposed_insulation, flood_cut damage, flooring_removed, peeling, rot, sagging, saturated materials, seam damage, staining, swelling, wall_material_removed, and wet damage conditions. The rule selection component generates evaluation strings that process room introspection including specialized surface detection for tile shower surrounds and tile tub surrounds, room size classification for areas measuring 100 square feet or less, 100-200 square feet, 200-300 square feet, and greater than 300 square feet. The rule application component processes complex rules including “parent_structure in [‘floor’] and material in [‘brick’, ‘carpet’, ‘concrete’, ‘generic’, ‘laminate’, ‘marble’, ‘other’, ‘stone’, ‘tile’, ‘vinyl’, ‘wood’] and subcategory in [‘carpet_removed’, ‘delamination’, ‘deteriorated’, ‘flooring_removed’, ‘peeling’, ‘saturated’, ‘stained’, ‘swelling’, ‘wet’] and room_type in [‘kitchen’]”. The evaluation engine supports both positive inclusion criteria for elements that must be present and negative exclusion criteria for elements that must not be present, enabling precise rule specification for complex damage scenarios. The lookup module accesses action matrices defining specific responses based on dynamic categories, selectors, actions, calculations, and line item information, the action matrices including automated formulas and manual calculation triggers. The rule application component generates evaluation strings that default to “False” when no conditions are specified, ensuring deterministic rule processing across all carrier-specific guideline applications.

In some examples, the 2D detector implements an object-oriented architecture utilizing a Room class that encapsulates spatial and damage analysis detectors, the Room class configured to extract spatial measurements from three-dimensional JSON data structures and maintain structured object hierarchies linking damage instances to parent structural elements through unique identifier relationships. The 2D detector includes a threshold-based damage classifier utilizing nearly-zero constants for damage boundary detection, proportional damage assessment computing ratios of damaged versus total structural elements, and multi-state damage recognition distinguishing between removed, damaged, and intact structural elements. The rule management module implements an evaluation engine that processes complex conditional logic through structured enumeration systems, the evaluation engine maintaining material taxonomies including acoustic ceiling tiles, brick, carpet, concrete, fabric, gypsum, laminate, marble, stone, tile variations, vinyl, wallpaper, and wood classifications. The rule management module processes damage in relation to structural contexts including ceiling, floor, and interior wall classifications, applies room-specific logic for bathroom, kitchen, and laundry environments, and evaluates comprehensive damage classifications including carpet removal, ceiling material removal, delamination, deterioration, drywall removal, exposed insulation, flood cuts, flooring removal, peeling, rot, sagging, saturation, seams, staining, swelling, wall material removal, and wet damage conditions.

In some examples, the rule-based converter engine generates dynamic evaluation strings through a BaseModel architecture that processes inclusion and exclusion criteria for parent structures, materials, damage subcategories, and room types, constructing complex boolean expressions combining multiple criteria with AND logic operators. The three-dimensional reconstruction engine is configured to perform operations comprising: receiving, by a computing system, a 2D image representing at least a portion of a physical scene; processing the 2D image using a trained depth estimation model, the depth estimation model comprising a neural network configured to predict, for each pixel in the 2D image, a depth value representing a relative distance of a corresponding portion of the physical scene from a viewpoint associated with the 2D image; generating a depth map comprising a plurality of depth values corresponding to a plurality of pixels in the 2D image; constructing a 3D point cloud by projecting each pixel of the 2D image into a 3D coordinate space using its corresponding depth value and intrinsic parameters of a virtual camera model; generating a 3D surface model based on the 3D point cloud; and rendering the 3D surface model for display on a user interface. The two-dimensional detector is configured to apply rule-based logic to evaluate the presence, absence, and spatial extent of visual features in the unstructured multimedia input data to classify architectural elements as fully damaged, partially damaged, or removed. The rule-based logic comprises logical conditions that include: determining whether a damage region overlaps a building material region by more than a predefined threshold; detecting the absence of expected material boundaries within a specified spatial zone; or identifying whether all detected material boundaries intersect one or more damage regions.

In some examples, the two-dimensional detector is further configured to assign, for each detected architectural element, a categorical damage classification based on outputs of rule-based classifiers that analyze semantic segmentation masks, damage region overlays, and edge detection features extracted from the multimedia input data. The actions include a hardware storage device storing computer executable logic representing rules; wherein the rule-based converter engine is configured to receive an output from the metadata generator and to read the computer executable logic from the hardware storage device; wherein the rule-based converter engine is further configured to execute the computer executable logic against the output received from the metadata generator to generate a report; and wherein the rule-based converter engine is further configured to store the report in the hardware storage device for subsequent retrieval.

A system of one or more computers can be configured to perform particular operations or actions by virtue of having software, firmware, hardware, or a combination of them installed on the system that in operation causes or cause the system to perform the actions. For example, a system includes one or more processors and one or more machine readable hardware storage devices storing instructions that are executable by the one or more processors to perform one or more of the foregoing operations of the foregoing system. One or more computer programs can be configured to perform particular operations or actions by virtue of including instructions that, when executed by data processing apparatus, cause the apparatus to perform the actions.

In some examples, a method implemented by a data processing system comprises accessing unstructured, multimedia input data including one or more: images, videos, three-dimensional data, point cloud data, voice recordings, drawings, or scanned assets associated with a physical interior space; receiving the unstructured, multimedia input data and executing computer vision logic on the received unstructured, multimedia input data to detect one or more building materials, one or more damage patterns, one or more architectural elements, and to extract dimensional information; reconstructing (e.g., generating) a metrically accurate three-dimensional model of the physical interior space from the input data; generating structured metadata from outputs of the two dimensional detector and the three-dimensional reconstruction engine, the structured metadata including one or more quantitative measurements, one or more material classifications, one or more structural damage assessments, dimensional data, and one or more confidence scores; and processing the structured metadata in accordance with a set of externally defined, carrier-specific rules to generate one or more claims estimate reports, the rule-based converter engine comprising an output generation component configured to produce reports, two-dimensional data, three-dimensional data, and supporting documentation formatted according to the carrier-specific rules. In this example, the method also comprises the foregoing actions described with regard to the system claim.

In some examples, one or more machine-readable hardware storage devices store instructions that are executable by one or more processing devices to perform operations comprising: accessing unstructured, multimedia input data including one or more: images, videos, three-dimensional data, point cloud data, voice recordings, drawings, or scanned assets associated with a physical interior space; receiving the unstructured, multimedia input data and executing computer vision logic on the received unstructured, multimedia input data to detect one or more building materials, one or more damage patterns, one or more architectural elements, and to extract dimensional information; reconstructing (e.g., generating) a metrically accurate three-dimensional model of the physical interior space from the input data; generating structured metadata from outputs of the two dimensional detector and the three-dimensional reconstruction engine, the structured metadata including one or more quantitative measurements, one or more material classifications, one or more structural damage assessments, dimensional data, and one or more confidence scores; and processing the structured metadata in accordance with a set of externally defined, carrier-specific rules to generate one or more claims estimate reports, the rule-based converter engine comprising an output generation component configured to produce reports, two-dimensional data, three-dimensional data, and supporting documentation formatted according to the carrier-specific rules. In the example, the operations further comprises the action described with regard to the foregoing system claim.

### DESCRIPTION OF DRAWINGS

FIG. 1 illustrates an example system architecture.

FIG. 2 illustrates a 2D detector.

FIG. 3 illustrates a metadata generator.

FIG. 4 illustrates a converter engine with multi-module structure.

FIG. 5 illustrates a feedback interface integration throughout the pipeline.

FIG. 6 illustrates a process for generating semantically structured three-dimensional scene representations from unstructured multimedia input data.

FIG. 7 is a diagram of an example computer system.

### DETAILED DESCRIPTION

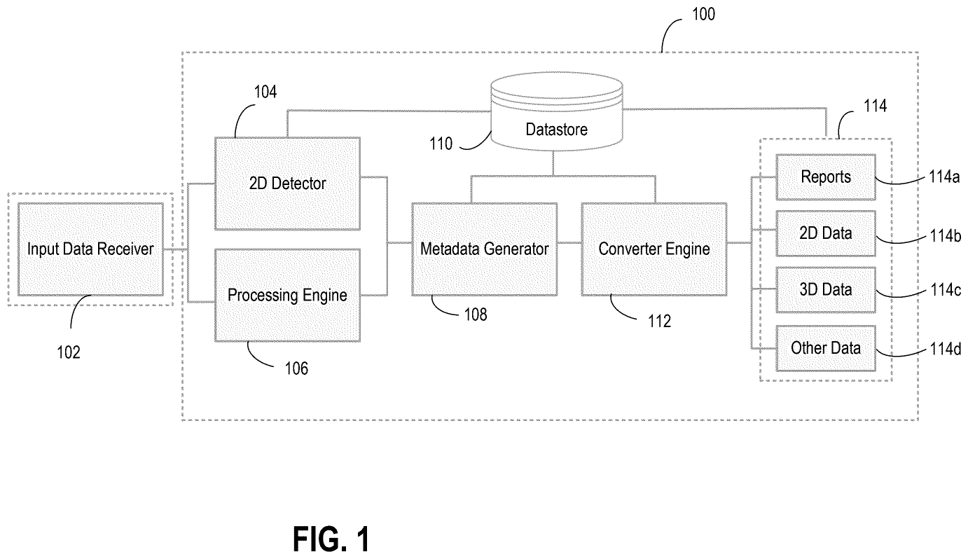

Referring to FIG. 1, system 100 is shown with input data receiver 102 that receives input data in multiple media formats and processes this data to generate accurate building damage assessments and claims reports. The system 100 includes multiple interconnected processing modules that work in coordination to transform raw input data into structured assessments suitable for property insurance claim processing.

The input data receiver 102 accepts a wide variety of input data types, providing flexibility and comprehensive coverage for damage assessment scenarios. The input data includes digital images captured by smartphones, cameras, or other imaging devices, video recordings from various sources including handheld devices, drones, or security systems, textual descriptions and notes related to the damage, three-dimensional data captured through specialized scanning equipment, point cloud data generated by LiDAR or photogrammetry systems, voice recordings containing verbal descriptions of damage, architectural drawings, or sketches in both hand-drawn and digital formats, scanned assets including documents, photographs, or other relevant materials, and additional multimedia formats as they become available.

In some examples, the system 100 includes another processing engine not shown) that accesses two primary processing engines 104, 106 operating in parallel to analyze the input data. The 2D detector 104 employs 2D detection, including but not limited to vision-based large language models or vision-based segmentation and detection methods to determine an understanding (i.e., identify a semantic meaning) of a scene specified by the input data. The 2D detector 104 analyzes the input data to identify and classify different types of building materials, detect and quantify damage patterns and severity, recognize architectural elements and structural components, extract dimensional information from the scene, and understand spatial relationships between objects and damage areas. An architectural element, in the context of building analysis and 3D scene reconstruction, refers to any physically or visually distinct component of a built environment that contributes to the structure, layout, or aesthetic of an interior or exterior space. These elements can be structural, functional, or decorative and are typically recognizable components of buildings.

The processing engine 106 (also referred to as a three-dimensional reconstruction engine) transforms two-dimensional input data into comprehensive three-dimensional representations using 3D computer vision to reconstruct 3D models from multiple 2D images that can determine camera positions and scene geometry, depth estimations, surface normal maps, and the integration of existing 3D data with reconstructed models, and global alignment procedures to ensure accuracy, as described in U.S. Pat. No. 11,423,615 and US-2025-0148709-A1, the entire contents of each of which are incorporated herein by reference.

Constructing a 3D image from a 2D image involves estimating the depth and spatial structure that are not explicitly present in the original flat image. In some examples, the system described herein uses deep learning models trained for depth estimation. In this process, the 2D image is first preprocessed—typically resized and normalized—before being passed into a neural network, such as a convolutional neural network (CNN) or a vision transformer, that has been trained to predict depth information from single images. The output is a depth map, which assigns a relative depth value to each pixel, effectively describing the distance of objects from the camera. This depth map can then be combined with the original image and camera parameters to generate a 3D point cloud, which represents the geometry of the scene in three-dimensional space. If desired, the point cloud can be further processed to create a continuous 3D mesh using surface reconstruction techniques.

In cases where multiple 2D images from different viewpoints are available, the system uses multi-view stereo techniques. This begins with calibrating the cameras to determine their internal parameters and relative positions. Features are then extracted and matched across the various images, and depth is calculated via triangulation of these correspondences. The result is a dense 3D reconstruction of the scene, often with greater precision than single-image methods. Both single-image and multi-image techniques may ultimately produce a textured 3D model suitable for visualization, simulation, or further analysis.

Both 2D detector 104 and the processing engine 106 generate structured metadata received by a receiver that serves as input for the converter engine 112 (e.g., also referred to as a rule-based converter engine). In some examples, system 100 includes metadata generator 108 that generates structured metadata from outputs of 2D detector 104 and processing engine 106. The metadata includes quantitative measurements of damaged areas, material classifications and properties, structural damage assessments, dimensional data including square footage and volume calculations, photographic evidence with associated spatial coordinates, and confidence scores for automated assessments.

The structured metadata generated by the system (e.g., metadata generator 108) represents a machine-readable summary of the physical scene, including information such as material classifications, spatial measurements, damage assessments, and confidence scores. This metadata is essential for downstream tasks like generating insurance reports, estimating repair costs, or verifying building code compliance. To produce this metadata accurately and reliably, the system combines both two-dimensional detection and three-dimensional scene reconstruction (e.g., performed by processing engine 106).

The 2D detector is responsible for identifying visual cues from input images or videos—such as the presence of specific materials, edges, textures, or visible damage patterns. However, while 2D analysis may detect where in an image damage appears, it lacks spatial context. Without understanding depth, scale, or object orientation, the system cannot determine how much surface area is affected or distinguish between a damaged floor and a similarly colored wall, particularly if the image is poorly aligned or distorted. This is where 3D reconstruction becomes necessary.

By reconstructing a metrically accurate 3D model of the space, the system gains an understanding of real-world dimensions and relationships between objects and surfaces. It can accurately determine whether damage is located on a floor, wall, or ceiling and compute precise measurements of affected regions—such as square footage of damaged drywall or volume of water intrusion. This spatial awareness allows the system to assign geometric and categorical labels to detected features and relate them to specific architectural elements.

The metadata generator then integrates the outputs from both the 2D detector and the 3D reconstruction engine. It projects detected features onto the 3D model to compute real-world metrics, assigns semantic labels based on material type and position, and generates location-specific information such as spatial coordinates and area measurements. It may also include photographic references and assign confidence scores reflecting the system's certainty in its assessments. Without the 3D understanding of the scene, this structured metadata would lack the accuracy and spatial grounding needed for automated reporting and decision-making.

For example, the structured metadata can include a three-dimensional representation of the scene. In fact, in some embodiments, the 3D model generated by the system serves as a foundational component of the metadata, providing a spatial framework into which other forms of semantic information can be embedded. The 3D reconstruction engine produces a metrically accurate model of the physical space, capturing geometric features such as surfaces, dimensions, and object boundaries. This model is not just a visual rendering—it can be encoded as structured data that describes the shape, size, position, and orientation of architectural elements like walls, floors, windows, and furniture.

Once the 2D detector processes the multimedia input and identifies features such as materials and damage regions within flat images, those findings are projected—or overlaid—onto the reconstructed 3D model. This projection allows the system to translate pixel-level observations into real-world spatial coordinates. For example, if a region of damage is detected in a photograph, the system can determine where that region lies on a 3D surface and how much physical area it covers. In doing so, the system produces metadata that not only labels an object as damaged, but also quantifies the extent of that damage in square footage and associates it with a specific location in three-dimensional space.

The structured metadata thus includes both semantic classifications (e.g., material type, damage type, confidence level) and spatial attributes (e.g., location, size, orientation) anchored in the 3D model. In this way, the metadata reflects a deep integration of 2D visual analysis and 3D spatial understanding, enabling more accurate, measurable, and context-aware representations of the built environment.

The converter engine 112 receives the generated metadata from metadata generator 108 and accesses datastore 110, which stores data specifying third-party guidelines specific to different insurance carriers (e.g., data specifying rules, code specifying rules, and so forth). Converter engine 112 applies the accessed data (e.g., executes the code) to the received metadata. In some examples, the converter engine 112 processes this information (e.g., the received metadata) in conjunction with carrier-specific rules and requirements to generate comprehensive output data (e.g., output 114). The third-party guidelines provide carrier-specific processing rules, regulatory requirements, regional pricing information, and industry standards that ensure compliance with various insurance company policies.

The system 100 produces output 114 and stores output 114 in one or more data stores. There are different types of output 114, including, e.g., multiple output formats organized into distinct categories. The reports engine 114a generates comprehensive claims assessment documents formatted according to carrier specifications, including detailed damage assessments, cost calculations based on regional labor and material prices, repair methodology recommendations, and timeline estimates for restoration work. The 2D data engine 114b produces floor plans, damage diagrams, and photographic documentation suitable for traditional claims processing workflows. The 3D data engine 114c creates 3D models, including parametric 3D models and point clouds. The other data engine 114d includes measurements, material lists, cost breakdowns, and supporting documentation necessary for comprehensive claims processing as integrated into claims estimation software.

For example, the converter engine transforms the structured metadata into final output reports that are tailored to the needs of different insurance carriers. Once the metadata generator has produced structured data—such as measurements, material classifications, and damage assessments—that metadata is passed to the converter engine.

The converter engine then consults a datastore, which contains predefined processing rules, logic, or code written to reflect the specific requirements of third parties—in this case, different insurance companies. These third-party guidelines may include things like regional pricing databases (e.g., cost per square foot for replacing drywall), regulatory constraints (e.g., code compliance requirements), policy-specific thresholds (e.g., when damage is deemed total loss), and formatting requirements for different carriers.

Using this information, the converter engine processes the metadata accordingly. For instance, if the metadata says a wall has 24 square feet of water damage, the converter engine may use the carrier's pricing model to assign a cost to that repair, check whether the extent of damage triggers a replacement policy, and format the results into a report compatible with that insurer's system. It may also execute code stored in the datastore to apply more complex rules or calculations.

In doing so, the system produces output data—such as insurance estimate reports, 3D visual summaries, or structured claim files—that are automatically compliant with the rules and expectations of specific insurers. This ensures consistency, regulatory compliance, and streamlined claims processing for each insurance partner.

In some examples, the converter engine includes one or more types of systems, including, e.g., a deterministic system, a probabilistic system, a generative system, an agentic system and so forth.

In this example, a deterministic system refers to a component of the converter engine that processes structured metadata using a predefined set of rules to generate consistent, repeatable outputs. It always produces the same result when given the same input, without relying on probabilistic inference or machine learning. When generating an insurance report or repair estimate, the deterministic system takes metadata such as material type, damage classification, location, area, and confidence scores, and applies rule-based logic that reflects the specific requirements of an insurance carrier.

For example, suppose the metadata indicates that a wall contains 24.6 square feet of water-damaged drywall. The deterministic system might apply a carrier-specific rule stating that if drywall is water-damaged and the affected area exceeds 20 square feet, the entire panel must be replaced. It would then look up the appropriate cost—for instance, $3.75 per square foot—and calculate a repair estimate of $92.25. In addition, it may generate a standard text description such as: “Replace damaged drywall on east wall covering approximately 24.6 square feet.” These outputs are produced through fixed decision trees, lookup tables, and templated logic.

Deterministic processing ensures that similar claims are handled consistently, that all business rules are enforced precisely, and that every step of the output is auditable and explainable. In this way, the deterministic system within the converter engine allows for the automated generation of formatted reports, cost estimates, and documentation that align with third-party specifications, all without introducing variability or uncertainty.

In another example, a probabilistic system is designed to handle uncertainty, ambiguity, or incomplete information in the structured metadata. It uses statistical models to infer the most likely interpretation or outcome based on prior data, learned distributions, or confidence thresholds. For example, suppose the 2D detector identifies what appears to be damage on a wood floor, but the segmentation mask is noisy and the confidence score for that classification is relatively low—say, 0.61. Additionally, the detected region partially overlaps both a wood floor and a rug, making it unclear whether the damage applies to the flooring, the rug, or both.

A probabilistic system is coded with logic based on prior probabilities (for instance, learned from a training set of thousands of claims) to reason that when damage is detected in this type of region with a certain texture and pattern, there's a 75% chance it is hardwood floor damage, a 15% chance it's rug staining, and a 10% chance it's a lighting artifact. It can then weigh these possibilities and generate a confidence-weighted classification, recommending a repair action for the floor while marking the result with a flag indicating medium confidence. It might also estimate the likelihood that the damage area exceeds a replacement threshold, even when boundaries are incomplete. The final report could include this analysis, stating: “Probable hardwood damage detected on southwest quadrant; estimated affected area: 14.8 square feet; confidence level: moderate.” This allows for more flexible and intelligent processing when the data is noisy or unclear—an essential capability in real-world scenarios where image quality, lighting, or occlusions create uncertainty.

A generative system within the converter engine includes logic to synthesize human-readable or machine-usable content by transforming structured metadata into formatted outputs, often using templating mechanisms, natural language generation (NLG), or transformer-based language models. In this example, a generative system may output narrative summaries, documentation, or structured data representations that are contextually rich and linguistically coherent.

For example, suppose the metadata includes: a classification of drywall on the north-facing wall; a damage type of “saturation”; an affected area of 36.2 square feet; and a confidence score of 0.95. The generative system receives this data, and, based on a predefined output schema, constructs a descriptive sentence using a neural text generation model or rule-based template engine. The output might read: “The north wall contains approximately 36.2 square feet of saturated drywall, likely requiring full panel replacement. Observations indicate a high confidence in material classification and damage assessment.” This output can be embedded directly into a claims report, adjuster notes, or customer-facing documentation.

In more advanced configurations, the generative system may produce multi-paragraph summaries that integrate multiple data points across the scene-such as grouping related materials, describing spatial relationships between damaged elements, and explaining how observed patterns align with typical water intrusion profiles. The system can also produce machine-readable documents in JSON, XML, or PDF formats by populating complex schemas with metadata-driven content. That is, the generative system doesn't just create human-readable summaries (like descriptive sentences), but it can also automatically generate structured digital files—the kind that software systems (like insurance platforms, databases, or billing systems) can directly read and process.

An agentic system within the converter engine refers to a subsystem configured to operate autonomously or semi-autonomously, with the ability to make decisions, take actions, and respond to changes in data or system state based on defined goals, rules, and context. In technical terms, it may be implemented using rule-based agents, decision graphs, finite-state machines, or reinforcement-learning-based logic.

For example, imagine a case where the structured metadata identifies water damage in multiple areas of a room—drywall, baseboards, and flooring—with varying confidence levels and damage severities. The agentic system might be tasked with selecting the correct estimation strategy or routing logic based on dynamic conditions. It might begin by checking whether the damage meets a predefined threshold for total wall replacement. If it does not, the system may then check whether the affected surface area requires escalation to a human adjuster, based on confidence thresholds and carrier-specific policies. If the damage is borderline (e.g., moderate severity with low confidence), the agentic system might trigger a follow-up task: flag the case for supplemental image review or request additional documentation.

In this way, the agentic system monitors its own inputs and outputs, and decides which module to invoke next—whether it's a cost estimator, a text generator, a compliance validator, or a human-in-the-loop review process. It can dynamically select different processing paths, adapt to evolving data (e.g., if new metadata is added), and operate conditionally based on carrier policies, risk profiles, or user configurations. Some implementations may include a goal-state planner that evaluates end conditions (e.g., “Has all required output for Carrier A been generated with sufficient confidence?”) and autonomously works through the necessary actions to get there. The agentic system adds behavioral flexibility to the converter engine—it doesn't just apply rules or models, it decides what to apply, when to apply it, and whether further action is needed, based on ongoing evaluation of the data and policy context. This is especially valuable in complex or borderline cases, where automated systems need to emulate aspects of human judgment or orchestrate multi-step workflows.

The system 100 is designed for seamless integration with existing insurance industry systems through standardized APIs and data formats. The modular architecture allows for customization based on specific carrier requirements while maintaining consistency in core processing capabilities. The system 100 incorporates multiple validation mechanisms to ensure accuracy and reliability of generated assessments, including cross-referencing with historical data, consistency checking across multiple input sources, and confidence scoring for all automated determinations.

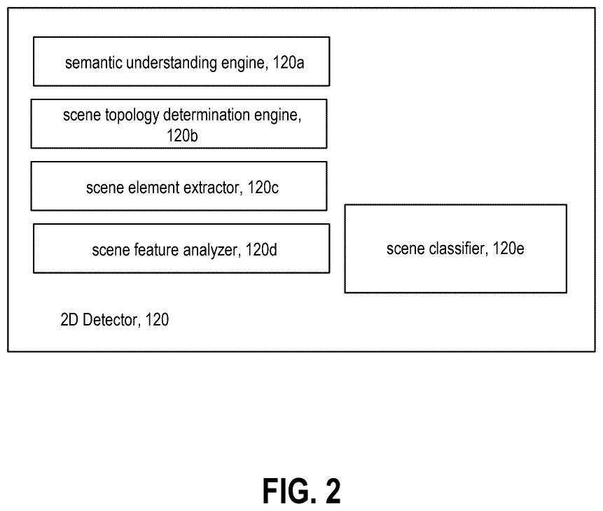

Referring to FIG. 2, the system includes 2D detector 120 configured to analyze input data and extract structured semantic, spatial, and material-related metadata relevant to building damage assessments. 2D detector 120 employs a combination of computer vision, deep learning neural networks, and semantic parsing techniques to detect and quantify building elements, material conditions, and damage states from diverse multimedia inputs.

2D detector 120 comprises multiple integrated engines responsible for distinct analytic functions. These may include, but are not limited to semantic understanding engine 120a, scene topology determination engine 120b, scene element extractor 120c, scene feature analyzer 120d, and scene classifier 120e. These engines may operate in parallel or in sequence depending on the system configuration and data complexity. The 2D detector 120 is configured to identify and classify architectural materials such as carpet, drywall, tile, wood, laminate, and stone. It applies object detection algorithms and image segmentation techniques to isolate surfaces and materials, determine their boundaries, and assess their condition. The system (e.g., 2D detector) detects a wide range of damage conditions including, but not limited to: delamination, deterioration, saturation, peeling, staining, moulding removal, and structural displacement.

In some examples, the 2D detector 120 is a modular computer vision component that decomposes the complex task of interpreting 2D imagery into a series of specialized analytic stages, each handled by a different sub-engine. These engines—labeled 120a through 120c—may operate in parallel or in sequence, depending on system configuration, hardware availability, and input data complexity.

The process often begins with the semantic understanding engine 120a, which is responsible for high-level contextual interpretation of the scene. This engine uses deep learning models—typically convolutional neural networks or transformer-based architectures—trained on labeled datasets to assign semantic meaning to pixels or regions in the image. For example, it may label a region as “drywall,” “tile,” or “window.” It builds a scene-wide semantic map that provides a foundational understanding of what types of materials or surfaces are present.

Next, the scene topology determination engine 120b analyzes the spatial layout of the environment as inferred from the image. It interprets depth cues (e.g., occlusions, perspective lines, shading), relative positioning, and boundary alignments to determine how surfaces are arranged with respect to one another. This engine may infer relationships such as “floor meets wall,” “cabinet is mounted on wall,” or “ceiling spans above all other elements.” The output is a structured spatial model—or 2.5D scene graph—that represents how major surfaces and architectural features are positioned and oriented.

Following that, the scene element extractor 120c isolates specific physical components from the image, such as baseboards, window frames, light fixtures, or countertops. While semantic understanding labels general materials, the extractor identifies distinct objects or boundaries of architectural elements using edge detection, region-growing, or instance segmentation algorithms. It plays a key role in mapping discrete architectural features to meaningful real-world objects that can be quantified or measured.

The scene feature analyzer 120d focuses on low- and mid-level visual characteristics, such as color, texture, reflectance, and damage indicators. It evaluates these features to determine the surface condition of materials, detecting subtle signs of deterioration such as water staining, mold growth, or delamination. For example, it might detect discoloration patterns that suggest saturation or texture inconsistencies indicating blistering or peeling paint. This analysis supports downstream damage classification and condition assessment.

Finally, the scene classifier 120e integrates inputs from the previous engines to assign categorical labels to identified features and surfaces. It applies rule-based or learned classification models to generate outputs such as: “tile with water damage,” “missing baseboard,” or “peeling drywall.” These classifications can be binary (e.g., damaged/not damaged) or multi-class (e.g., no damage, minor, moderate, severe), and they serve as the basis for generating structured metadata.

Together, these engines enable the 2D detector 120 to robustly interpret unstructured image or video input. Through their combined operation, the system can identify architectural materials like carpet, wood, or laminate; isolate and map their boundaries; detect a variety of damage conditions (e.g., staining, saturation, peeling, moulding removal); and produce machine-readable outputs that link visual features to semantic and spatial meaning. This layered, engine-based architecture ensures scalability and modularity, allowing the system to adapt to different scene types, resolutions, or analytic goals.

A spatial engine within 2D detector 120 interprets room geometry from 3D data structures, extracting dimensional measurements such as floor area, ceiling height, and volumetric space. This spatial metadata (e.g., dimensional measurements) supports precise damage quantification and repair scope determination. The system employs a hierarchical object structure in which damage annotations are linked to parent architectural components (e.g. baseboards, walls, doors), allowing for structured relationships between damage instances and the overall building layout. Each object is uniquely identified and tracked through a scene-specific object graph.

In one embodiment, 2D detector 120 implements boolean logic frameworks to differentiate between fully damaged, partially damaged, and removed building components using rule-based classifiers. Examples include state assessments such as all moulding removed, some moulding damaged, and all moulding removed or damaged, each determined through spatial extent analysis and damage polygon evaluation.

In one embodiment, the 2D detector 120 is configured to analyze visual input—such as images or video frames—captured from a physical interior space to detect and evaluate the condition of building components. The detector applies a set of rule-based classifiers that use boolean logic frameworks to categorize the state of individual architectural elements, such as baseboards, moulding, drywall, or cabinetry, as either fully damaged, partially damaged, or removed.

A boolean logic framework, as used herein, refers to a system of logical operations based on boolean algebra, in which variables representing binary conditions (e.g., presence/absence, damaged/intact) are combined using logical operators such as AND, OR, and NOT. Within this framework, each rule-based classifier is implemented as a decision logic tree or expression graph in which combinations of visual and geometric predicates are evaluated to yield a categorical outcome. These predicates may include conditions such as “damage polygon present,” “material region detected,” “area threshold exceeded,” or “expected edge feature missing.”

For example, a classifier using a boolean logic framework may define the state “all moulding removed” as true if the expression NOT (moulding_present_in_expected_region)
evaluates to true over the spatial extent of a wall-floor junction. A separate classifier for “some moulding damaged” may evaluate whether
moulding_present AND (damage_polygon_overlap>threshold)
is true. Another classifier for “all moulding removed or damaged” uses an OR operation:
(moulding_removed) OR (moulding_damaged).

The classifiers operate on a combination of semantic segmentation masks, bounding boxes, edge detections, and damage maps derived from earlier stages in the image processing pipeline. These inputs are derived using machine learning-based feature extractors and spatial analysis routines. The boolean logic framework then integrates these features into interpretable and deterministic rule structures, enabling precise classification of material conditions without relying solely on opaque model predictions.

Each classifier may also be parameterized to account for project-specific tolerances, material types, or context-specific considerations (e.g., differences in lighting or camera angle). The output of the classifier logic is used to generate structured metadata that characterizes the condition of architectural elements in a consistent, machine-readable format for use in automated estimating systems, insurance workflows, or repair planning modules.

The system described herein further includes material subtype filtering engine that correlates damage types with associated material categories. This allows for precise alignment between the identified damage and appropriate repair actions, improving accuracy in downstream computation and rule processing. 2D detector 120 also incorporates specialized detectors for structural elements such as lighting fixtures (e.g., recessed, flush mounted, wall mounted), plumbing fixtures (pedestal sinks) and architectural features (e.g. wood paneling, tile surrounds). These detectors employ feature-based and neural recognition models to accurately catalog specialized elements and their associated states. Upon completion of processing, 2D detector 120 generates structured metadata including measurements, object classifications, material types, spatial relationships, and confidence values. This metadata is transmitted to the converter engine 112, where it is combined with third-party insurance guidelines to produce policy-compliant claims estimates. In some embodiments, error handling mechanisms are integrated into the 2D detectors to manage invalid inputs, missing data, or structurally inconsistent scenes. These include invalid polygon detection, parent-child structure validation, and exception logging subsystems.

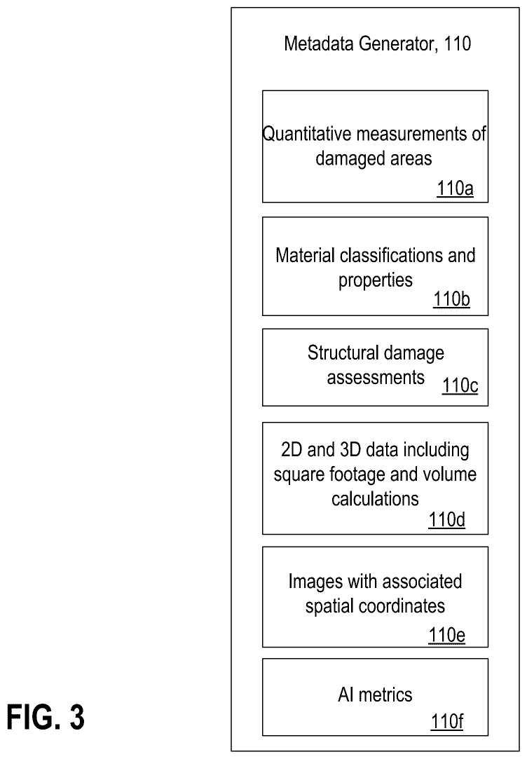

Referring to FIG. 3, metadata generator 110 receives processed outputs from upstream components such as 2D detector 104 and processing engine 106. Metadata generator 110 converts visual, spatial, and structural information into structured metadata that serves as input to converter engine 112.

The metadata generated by metadata generator 110 encapsulates a wide array of data attributes essential for damage estimation and compliance processing. It includes quantitative measurements of damaged areas 110a, such as surface dimensions and volume estimates, which are derived from the spatial and scene analysis components. Material classifications and their associated properties 110b are also encoded, enabling the system to distinguish between surface types, construction materials, and finish levels relevant to repair methodologies.

Additionally, the metadata includes structural damage assessments 110c, which reflect the severity and extent of physical damage across architectural components such as floors, walls, ceilings, and fixtures. These assessments are paired with dimensional data 110d including square footage calculations and volumetric measurements of affected regions.

To support visual validation and traceability, metadata generator 110 also includes photographic evidence annotated with corresponding spatial coordinates 110e. These coordinates allow precise mapping between visual content and three-dimensional scene reconstructions. Each data point within the metadata is further augmented with confidence scores (e.g., artificial intelligence (AI) metrics 110f), which indicate the system's level of certainty regarding its automated assessments. These scores are generated based on model accuracy metrics, detection consistency, and alignment across multiple data sources.

By structuring the output in this manner, metadata generator 110 produces a robust and interpretable data package that facilitates downstream processing, carrier-specific rule application, and accurate claims estimation within the converter engine 112. Additional details on each form of metadata generated are now provided, below.

Metadata 110a refers to quantitative measurements of damaged areas, such as square footage, linear dimensions, or volume. These measurements begin with the 2D detector 104, which uses image segmentation and object detection models to isolate regions of visible damage in 2D images—such as stains, cracking, delamination, or mold growth. The detector produces pixel-level masks or vector-based polygons outlining the damaged areas. These 2D regions are then projected into three-dimensional space by the processing engine 106, which reconstructs a metrically accurate 3D model of the environment. Using camera calibration data and surface orientation from the 3D model, the system computes real-world area or volume metrics based on the geometry of the surfaces onto which the 2D regions are mapped. This allows damage regions that appear only as pixel clusters in 2D to be quantified in precise physical units, such as 6.2 square feet of saturated drywall on a vertical plane.

Metadata 110b captures material classifications and their associated physical properties. This metadata is derived through semantic segmentation performed by the 2D detector 104, which assigns class labels to visual regions in the input image, identifying materials such as drywall, carpet, wood, tile, or laminate. These labels are determined using deep learning models trained on large datasets of labeled architectural materials. The output of this segmentation is further refined by incorporating geometric cues from the 3D reconstruction-such as orientation, location within the scene, and proximity to known structural features (e.g., baseboards or door frames). Once a material is classified, it is linked to a knowledge base or ontology that defines associated properties like absorbency, fire resistance, or typical thickness. For example, a region identified as “vinyl plank flooring” may carry metadata specifying its water resistance level and standard repair cost per square foot.

Metadata 110c pertains to structural damage assessments and includes both the type and severity of damage. The 2D detector identifies visible damage indicators such as staining, peeling, warping, or cracking through learned visual features and damage-specific segmentation models. These observations are enriched by topological and depth information from the 3D reconstruction, which allows the system to determine whether the deformation is superficial (e.g., surface staining) or structural (e.g., displacement of framing elements or ceiling sagging). The damage type is then categorized—such as “minor water damage,” “moulding displacement,” or “material delamination”—and severity is assigned based on threshold criteria like area affected, depth deviation, or multi-layer material separation. This results in a structured damage assessment that includes type, location, and severity with associated confidence scores.

Metadata 110d includes dimensional data, such as surface area, wall height, room volume, and inter-object spacing. This metadata is generated primarily by the 3D reconstruction engine, which builds a metrically accurate point cloud or mesh model of the interior space. From this model, the system extracts geometric features like surface planes, bounding boxes, and distances between elements. It calculates key room-level attributes (e.g., floor area, ceiling height), and it assigns these dimensions to detected scene elements. These measurements are essential for generating repair estimates, validating code compliance (e.g., minimum ceiling height), or estimating material quantities. The dimensional data is anchored in real-world units and tied to spatial coordinates within the model.

Metadata 110e refers to confidence scores associated with all the above metadata types. These scores reflect how certain the system is about each detection or classification and are typically derived from model outputs (e.g., softmax probabilities from neural networks), rule-based thresholds (e.g., overlapping region percentages), or statistical correlation with known reference datasets. For instance, if the material classifier assigns a probability of 0.94 to “drywall” and the damage classifier assigns 0.91 to “water saturation,” both values may be propagated into the metadata as confidence levels. Additionally, multi-modal consistency checks—such as alignment between 2D visual features and 3D geometry—can raise or lower these scores. These confidence values allow downstream systems to prioritize, flag, or override uncertain assessments and enable human review when necessary.

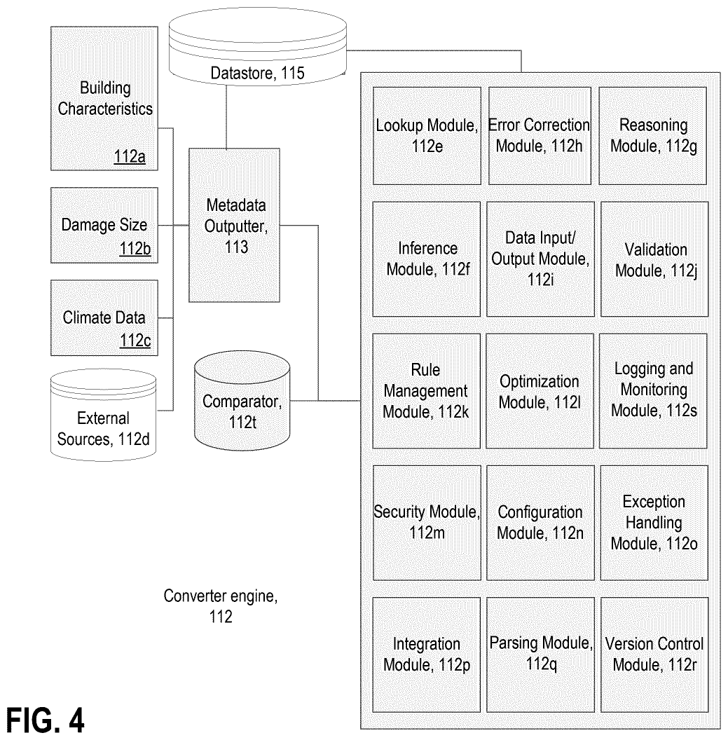

Referring to FIG. 4, converter engine 112 receives structured metadata generated by the upstream processing modules, including metadata generator 110. Upon receiving this metadata, the converter engine 112 applies a set of third-party guidelines that are specific to individual insurance carriers. Converter engine 112 may do so by executing a computer program that includes logic representing the rules (e.g., guidelines) and may input the received metadata into the computer program, such that the computer program executes with the metadata as input. These guidelines govern the logic, calculations, and procedural frameworks required for producing claims assessments that align with carrier expectations.

Using the metadata input, converter engine 112 processes the information to generate complete claims estimate reports. These reports include detailed cost breakdowns derived from regional labor rates and material pricing databases. The system calculates repair costs based on real-world pricing models and regional supply conditions. Additionally, the engine produces repair methodology recommendations that account for material compatibility, structural limitations, and regulatory compliance. Timeline estimates for completion of restoration work are also generated based on task duration models and regional labor availability.

The output generated by converter engine 112 is produced in multiple formats to suit a variety of carrier workflows and system requirements. These formats include formal report documents containing claims assessments structured according to insurer specifications. The system also produces two-dimensional data including annotated floor plans, labeled damage diagrams, and photo-documentation integrated with coordinate metadata. For enhanced visualization and immersive validation, the engine outputs three-dimensional models, reconstructed point clouds, and virtual reality-compatible renderings. Further, the system produces auxiliary data formats such as measurement logs, material inventories, cost matrices, and associated reference documentation.

To ensure operational flexibility and wide adoption, the system is built for seamless integration with third-party insurance platforms using standardized data formats and application programming interfaces. Its modular architecture enables customization based on carrier-specific needs, while maintaining consistency in processing logic, validation routines, and data governance protocols.

The converter 112 comprises a multi-module analytical system that serves as the central reasoning component of the invention. It receives data inputs from various sources including metadata outputter 113 (and/or a metadata generator) that outputs metadata derived from visual and spatial analysis, regional construction information, and external market databases. The engine applies a range of inferential and deterministic algorithms to evaluate property conditions and produce accurate insurance estimates.

The data processed by converter engine 112 includes building characteristics data 112a that specifies structural characteristics of the building, such as material types, construction methods, architectural layout, and code compliance factors. It also incorporates damage size data 112b that specifies quantitative damage measurements including surface areas, volumetric losses, and severity grading. Climate and environmental data 112c are taken into consideration as well, including prevailing weather conditions at the time of the event, seasonal factors, and region-specific patterns that influence repair strategies. Additionally, external sources 112d are referenced to retrieve real-time information on regional pricing, contractor availability, material cost fluctuations, and historical repair data.

The converter engine 112 includes cooperating modules designed to execute distinct aspects of the processing logic. These include core reasoning modules such as the Lookup Module 112e, which accesses from datastore 115 structured rule sheets and third-party pricing data using decision trees. Each rule sheet defines condition parameters such as location, material types, and damage characteristics. The system supports multiple rule configurations via a tabbed interface, allowing for scenario-specific switching between logic sets. These may include rules for conditions like flooring removal, subfloor exposure, bathroom-specific damages, or patterned carpet repair.

The Inference Module 112f within the engine uses artificial intelligence to complete logical pathways even when certain data points are missing, drawing probabilistic conclusions based on available context. The Reasoning Module 112g processes multiple decision variables simultaneously, applying weighted criteria and best practice models to generate optimized recommendations. Data exchange between internal and external sources is handled by the Data Input/Output Module 112i, which validates formats and ensures orderly data flow.

For quality control, the engine includes an Error Correction Module 112h that detects anomalies in the input data, applies statistical corrections, and flags inconsistencies. The Validation Module 112j checks outputs against known benchmarks and industry standards, ensuring all computations meet defined accuracy thresholds. A dedicated Rule Management Module 112k evaluates the metadata using highly structured enumeration logic and taxonomy libraries. This includes classification of material types such as wood, carpet, tile, vinyl, and drywall, as well as assessment of various structural categories like interior walls, ceilings, and floors. The engine applies specialized rules for bathroom, kitchen, and laundry areas, and evaluates damage states such as saturation, delamination, peeling, swelling, staining, and full material removal.

Using its rule evaluation framework, the system supports advanced logical expressions that include both inclusion and exclusion criteria. It constructs compound Boolean expressions such as: “parent_structure in floor, material in wood or tile, and damage_subcategory in flooring_removed and room_type in kitchen.” These expressions enable fine-grained control over how rules are applied across different architectural contexts.

The Rule Management Module 112k maintains and applies carrier-specific guidelines, regulatory requirements, and industry standards to ensure compliance with various insurance company policies. The Rule Management Module 112k implements a sophisticated evaluation engine that processes complex conditional logic through structured enumeration systems and dynamic string generation. The system maintains extensive material taxonomies including acoustic ceiling tiles, brick, carpet, concrete, fabric, generic materials, gypsum, gypsum popcorn, laminate, marble, stone, tile variations (standard tile, tile_shower, tile_tub), vinyl, wallpaper, and wood classifications. The rule engine processes damage in relation to specific structural contexts including ceiling, floor, and interior wall classifications, enabling context-aware rule application. The system applies room-specific logic for bathroom, kitchen, and laundry environments, allowing for specialized rule sets that account for room-specific damage patterns and repair requirements. The evaluation engine processes comprehensive damage classifications including carpet_removed, ceiling_material_removed, delamination, deteriorated surfaces, drywall_removed, exposed_insulation, flood_cut damage, flooring_removed, peeling, rot, sagging, saturated materials, seam damage, staining, swelling, wall_material_removed, and wet damage conditions. The system performs real-time room analysis including specialized surface detection for tile shower surrounds and tile tub surrounds, room size classification for areas measuring 100 square feet or less, 100-200 square feet, 200-300 square feet, and greater than 300 square feet, as well as contextual damage correlation with room features. The rule engine evaluates complex damage states including cabinet damage assessment for base, upper, tall cabinets, vanity, and toe kick damage. The system processes baseboard damage states encompassing all damaged, all removed, and partially damaged or removed conditions. Door damage categorization covers access, standard, pocket, bifold, and bypass door types. Moulding damage evaluation addresses complete, partial, and removed states. The engine performs dimensional damage assessment through height-based classifications of 0-1 feet, 1-3 feet, and 3-5 feet, as well as size-based damage thresholds for areas measuring 4 feet or less versus greater than 4 feet. The system generates dynamic evaluation strings through a sophisticated BaseModel architecture that processes inclusion and exclusion criteria for parent structures, materials, damage subcategories, and room types. The evaluation engine constructs complex boolean expressions by combining multiple criteria with AND logic operators. The system processes complex rules such as “parent_structure in [‘floor’] and material in [‘brick’, ‘carpet’, ‘concrete’, ‘generic’, ‘laminate’, ‘marble’, ‘other’, ‘stone’, ‘tile’, ‘vinyl’, ‘wood’] and subcategory in [‘carpet_removed’, ‘delamination’, ‘deteriorated’, ‘flooring_removed’, ‘peeling’, ‘saturated’, ‘stained’, ‘swelling’, ‘wet’] and room_type in [‘kitchen’]” and “parent_structure in [‘interior_wall’] and material in [‘tile’, ‘tile_shower’, ‘tile_tub’] and subcategory in [‘delamination’, ‘drywall_removed’, ‘peeling’, ‘saturated’, ‘stained’, ‘wall_material_removed’, ‘wet’] and room_type in [‘bathroom’] and room has_tile_shower_surround (damage)”. The evaluation system supports both positive inclusion criteria for elements that must be present and negative exclusion criteria for elements that must not be present, enabling precise rule specification for complex damage scenarios. The system generates evaluation strings that default to “False” when no conditions are specified, ensuring deterministic rule processing.

The engine also includes a set of system management modules. The Optimization Module 112l monitors internal processing efficiency and continuously adapts logic for improved throughput. Logging and monitoring are handled by a dedicated module 112s that tracks every processing step and provides a full audit trail for debugging and regulatory compliance. The Security Module 112m ensures that all data is processed and transmitted securely using encryption and access control policies. Configuration settings and user preferences are managed by a central Configuration Module 112n, which allows tuning of the engine's parameters for different deployment environments. The Exception Handling Module 1120 manages runtime errors gracefully, ensuring uninterrupted system performance.

For data integration and translation, the system includes an Integration Module 112p that manages external API communications, a Parsing Module 112q that handles data structure transformations, and a Version Control Module 112r that stores assessment history, algorithm versions, and rule change logs for traceability and reproducibility.

The engine operates according to a coordinated workflow that begins with input validation through the Data Input/Output Module 112i. The Parsing Module 112q then extracts and structures relevant information. The Lookup Module 112e retrieves market references, and the Reasoning and Inference Modules 112g, 112f generate initial assessments. As stated above, the Rule logic is applied by the Rule Management Module 112k, followed by output validation through the Error Correction and Validation Modules 112h, 112j. The Optimization Module 112l refines results for accuracy and performance. Final outputs are then delivered through the Data Input/Output Module 112i in the required formats.

All computation outputs are stored in a comparator database 112t, which enables longitudinal and regional analysis of claims assessments. The database supports benchmarking by comparing similar damage types across different properties, geographic areas, time periods, and construction methods. It also allows for trend detection, material evolution tracking, and regional pricing intelligence. The converter engine incorporates multiple layers of quality assurance. Validation mechanisms include cross-referencing historical data, detecting inconsistencies between input sources, and generating confidence scores for each determination. The system logs all decisions, flags anomalies, and supports human oversight where necessary.

This multi-layered, modular engine transforms traditional claims assessment workflows into a highly automated, accurate, and repeatable process. It provides the flexibility to incorporate new carrier guidelines while maintaining rigorous control over the integrity and consistency of outputs.

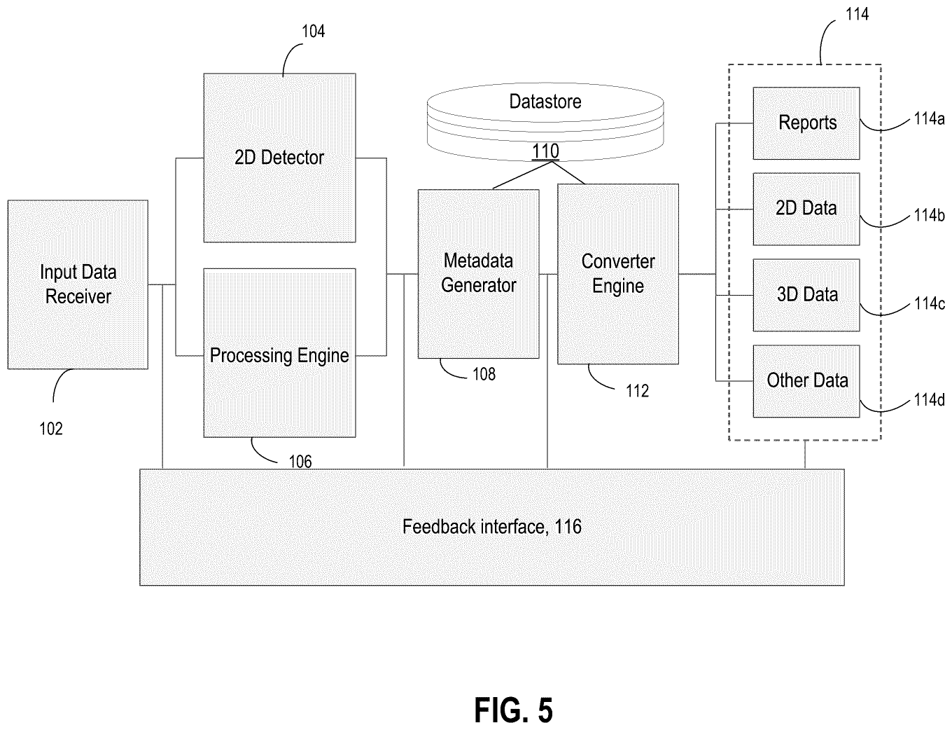

Referring to FIG. 5, feedback interface 116 provides one or more graphical user interfaces, e.g., for viewing by trained insurance professionals, certified adjusters, and technical specialists. The human operators access the system through authenticated web-based portals and specialized client applications that provide real-time visibility into select stages of the automated processing pipeline. These interfaces allow human experts to monitor automated processing as it occurs and intervene at any point where human judgment is required or where automated results require validation or correction. Human reviewers working through feedback interface 116 can examine and modify automated rule applications generated by the converter engine. When the system applies carrier-specific guidelines to damage scenarios, human adjusters can review the rule selection process and override or modify rule applications when automated logic produces inappropriate results. These human experts can substitute alternative rules, manually adjust rule parameters, and account for unique damage conditions that standard automated rule sets may not adequately address. The human operators can correct scene understanding processing outputs when automated object recognition, damage classification, or material identification produces errors. Human reviewers examine confidence scores for automated determinations and can manually correct misclassified objects, adjust incorrectly assessed damage severity levels, and verify structural element identification that may have been misidentified by computer vision algorithms. For 3D conversion processing, human validators working from specialized workstations equipped with 3D visualization capabilities can assess and correct spatial reconstructions, dimensional measurements, and geometric representations. These operators can manually adjust 3D models when automated processing fails to accurately represent physical damage environments or produces spatial inaccuracies. Human experts review and correct automated metadata extraction including measurements, calculated areas and volumes, and quantitative assessments. These specialists can validate automated calculations, manually correct measurement errors, and ensure that extracted metadata accurately represents observed damage conditions through direct intervention in the automated processing results.

During converter engine processing, human reviewers examine third-party guideline applications and can manually correct instances where automated rule application produces inappropriate cost estimates or repair recommendations. These operators can override specific rule selections, modify calculation parameters for unique circumstances, and manually adjust final estimates when human expertise identifies factors not adequately captured by automated processing. Human operators provide final review and correction capabilities for all system outputs including reports, cost calculations, repair recommendations, and technical documentation. These reviewers can manually edit automated report generation errors, adjust improperly computed cost calculations, and modify repair recommendations when automated processing fails to account for site-specific factors or specialized requirements. Feedback interface 116 maintains comprehensive tracking of all human interventions, corrections, and modifications applied throughout the processing pipeline. This documentation records original automated determinations alongside human corrections, providing feedback mechanisms for continuous system improvement and algorithm refinement based on patterns of human expert corrections and professional judgment applications.

The techniques described herein provide a technical improvement in the field of multi-view geometric reconstruction and volumetric scene understanding. Existing systems for spatial modeling typically rely on controlled inputs, such as structured scans or CAD (Computer-Aided Design) data, and often lack the ability to extract usable three-dimensional representations from heterogeneous and unstructured multimedia sources. In contrast, the techniques described herein leverage multi-view stereo, depth estimation, and global alignment methods to reconstruct metrically accurate three-dimensional models from ad hoc two-dimensional inputs, including images and video captured from arbitrary viewpoints. This reconstruction is not limited to generating visual models but includes the extraction of surface normal maps, spatial coordinates, and scene topology. The system enhances this core functionality with semantic labeling and hierarchical object parsing to generate structured metadata that reflects both spatial geometry and architectural meaning. These capabilities represent an advance over prior 3D reconstruction systems by enabling geometry-aware, semantically enriched models derived from uncurated, real-world inputs.

The techniques described herein apply this technical capability in a practical application involving interior structural analysis by generating spatially and semantically aligned three-dimensional outputs that can be processed under complex rule sets. This includes mapping object-level classifications such as wall, ceiling, or fixture onto volumetric structures, associating damage states with specific material subtypes, and supporting compliance workflows through output formats conforming to third-party specifications. Unlike conventional modeling systems that produce visual outputs for human interpretation, the techniques described herein create computationally actionable representations, which are further processed by a converter engine using deterministic and inferential logic modules. The ability to generate high-confidence, semantically structured 3D representations from uncontrolled inputs and feed them into domain-specific rule processors demonstrates a concrete improvement in computer vision and spatial computing systems, rather than a generic implementation of abstract processing steps.

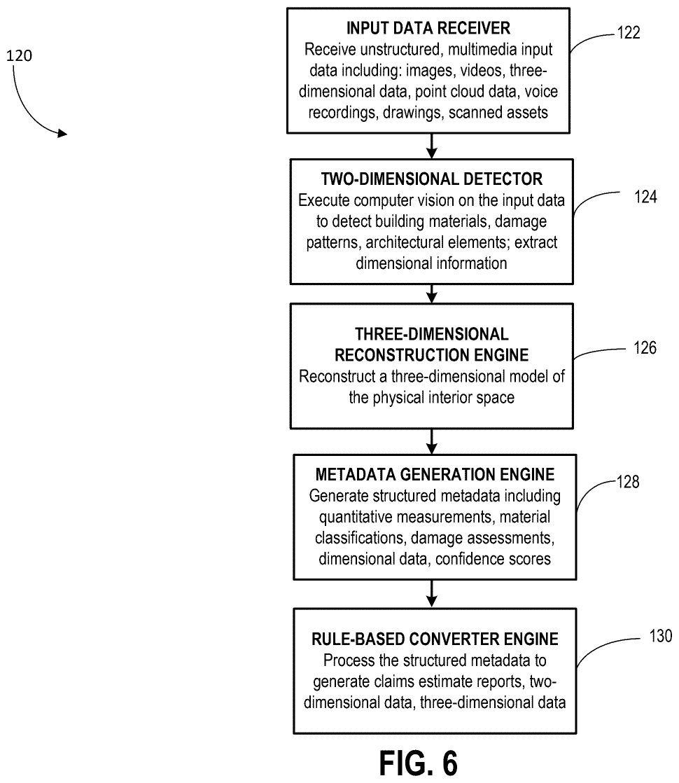

Referring to FIG. 6, process 120 is shown for generating semantically structured three-dimensional scene representations from unstructured multimedia input data. In operation, an input data receiver receives (122) unstructured, multimedia input data including one or more: images, videos, three-dimensional data, point cloud data, voice recordings, drawings, or scanned assets associated with a physical interior space. A two dimensional detector receives the unstructured, multimedia input data and executes (124) computer vision logic on the received unstructured, multimedia input data to detect one or more building materials, one or more damage patterns, one or more architectural elements, and to extract dimensional information. A three-dimensional reconstruction engine reconstructs (126) (e.g., generates) a metrically accurate three-dimensional model of the physical interior space from the input data. A metadata generation engine generates (128) structured metadata from outputs of the two dimensional detector and the three-dimensional reconstruction engine, the structured metadata including one or more quantitative measurements, one or more material classifications, one or more structural damage assessments, dimensional data, and one or more confidence scores. A rule-based converter engine processes (130) the structured metadata in accordance with a set of externally defined, carrier-specific rules to generate one or more claims estimate reports, the rule-based converter engine comprising an output generation component configured to produce reports, two-dimensional data, three-dimensional data, and supporting documentation formatted according to the carrier-specific rules, e.g., by executing logic specifying the set of externally defined, carrier-specific rules on the structured metadata to generate one or more claims estimate reports, the rule-based converter engine comprising an output generation component configured to produce reports, two-dimensional data, three-dimensional data, and supporting documentation formatted according to the carrier-specific rules. A real-world example of the foregoing process is now provided:

A property insurance adjuster is handling a claim for water damage following a plumbing failure in a residential apartment. To document the extent of damage, the policyholder submits a set of unstructured multimedia inputs, including smartphone photographs, a short video walk-through of the interior, and a LIDAR scan captured using a mobile device. These assets are uploaded to the system's input data receiver, which ingests (step 122) the collection of images, video frames, point cloud data, and any embedded spatial metadata (e.g., orientation, GPS location, and depth values).

The 2D detector then receives this unstructured input and executes computer vision logic (step 124) on the 2D content (i.e., images and video). It segments the visual data into labeled material regions—identifying drywall, baseboards, hardwood flooring, and tile. It also detects localized damage patterns, such as buckling, staining, and mold growth. Using convolutional neural networks and object detection models, it identifies architectural elements like window frames, door openings, and cabinetry. Based on relative object positions and reference features, the detector extracts preliminary dimensional estimates, such as height from floor to ceiling or wall surface area.

Next, the 3D reconstruction engine synthesizes the spatially resolved data (step 126) by integrating the 2D image features, video-derived structure-from-motion cues, and the raw point cloud from the LIDAR scan. It generates a metrically accurate 3D model of the affected rooms, complete with surface meshes for walls, floors, and ceilings. Detected 2D features (such as damage regions) are projected onto this 3D model, allowing precise localization and quantification of affected areas. For example, a water stain detected in the 2D imagery is mapped onto the 3D model of the north-facing wall and computed to span 8.3 square feet.

The metadata generation engine then compiles the system's findings (step 128) into structured metadata. It records that the north wall contains drywall classified as water-saturated, with a damage confidence score of 0.93. It includes quantitative metrics like area, volume, and depth (if measurable), assigns material classifications using a linked material ontology, and compiles geometric and positional metadata for each affected surface.

This structured metadata is standardized, meaning it is formatted according to a schema that ensures consistency across different use cases and insurance carriers. For example, all damage entries might follow a defined object model with pre-defined fields. This allows downstream systems—such as insurance platforms or estimation engines—to parse and interpret the data without ambiguity. Standardization may follow internal specifications or external standards like IFC (Industry Foundation Classes) or Xactimate-compatible formats.

Furthermore, each metadata element is tagged with spatial references within the 3D scene. This means that metadata records are not just flat text—they are linked to exact locations and surfaces in the 3D model using geometric coordinates or object identifiers. For example, the drywall damage is not only described as occurring on the “north wall,” but also linked to a specific mesh ID within the 3D scene graph and annotated with its bounding polygon in world coordinates. This allows users to visualize the metadata as overlays directly within the 3D model, enabling interactive inspection, measurement, and verification. These spatial tags support features like visual heatmaps, clickable damage summaries, and integration with augmented reality (AR) interfaces for in-field use.

The rule-based converter engine then processes this structured metadata (step 130) in accordance with predefined business rules provided by the relevant insurance carrier. These rules may include regional cost multipliers, policy thresholds, or mandated terminology. For instance, one rule may specify that if drywall damage exceeds 6 square feet with a confidence level above 90%, the system must recommend full panel replacement. The converter engine applies these logic rules deterministically to the metadata and uses a generative module to produce the final report. The output generation component formats the results as a claims estimate report that includes repair recommendations, cost estimates (e.g., $4.00/sq. ft. for drywall replacement), and accompanying visual documentation. It produces this output in multiple formats: a PDF for human review, a JSON payload for integration with carrier systems, and an interactive 3D model with annotated damage zones for adjuster validation.

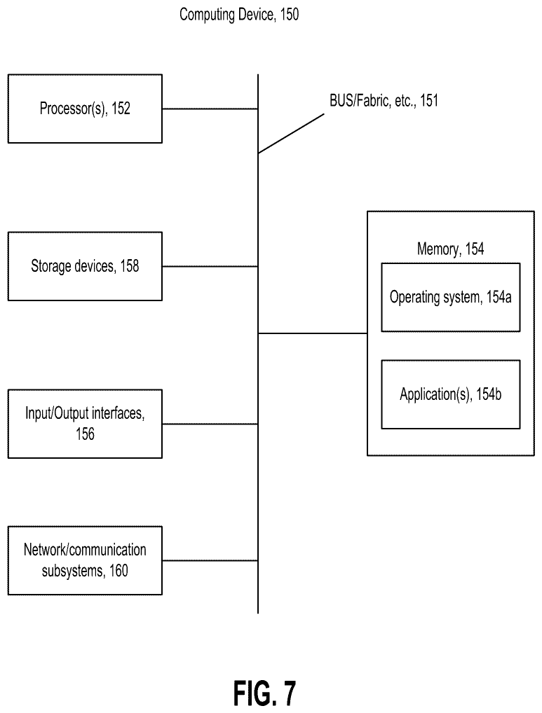

Referring to FIG. 7, an example operating environment for implementing embodiments of the present invention is shown and designated generally as computing device 150. The computing device 150 (also referred to as a computer or data processing system or client or server) includes one or more programmable processors 152 for performing actions in accordance with instructions and one or more memory devices 154 for storing instructions and data. Generally, a computer will also include, or be operatively coupled, (via bus 151, fabric, network, etc.) to I/O components 156, e.g., display devices, network/communication subsystems, etc. (not shown) and one or more mass storage devices 158 for storing data and instructions, etc., and a network communication subsystem 160, which are powered by a power supply (not shown). In memory 154, are an operating system 154a and applications 154b for application programming.

The computer program instructions and data may be stored in non-transitory form, such as being embodied in a volatile or non-volatile storage medium, or any other non-transitory medium, using a physical property of the medium (e.g., surface pits and lands, magnetic domains, or electrical charge) for a period of time (e.g., the time between refresh periods of a dynamic memory device such as a dynamic RAM). In preparation for loading the instructions, the software may be provided on a tangible, non-transitory medium, such as a CD-ROM or other computer-readable medium (e.g., readable by a general or special purpose computing system or device), or may be delivered (e.g., encoded in a propagated signal) over a communication medium of a network to a tangible, non-transitory medium of a computing system where it is executed. Some or all of the processing may be performed on a special purpose computer, or using special-purpose hardware, such as coprocessors or field-programmable gate arrays (FPGAs) or dedicated, application-specific integrated circuits (ASICs). The processing may be implemented in a distributed manner in which different parts of the computation specified by the software are performed by different computing elements. Each such computer program is stored on or downloaded (from a cloud computing infrastructure or other remote source) to a computer-readable storage medium (e.g., solid state memory or media, or magnetic or optical media) of a storage device accessible by a general or special purpose programmable computer, for configuring and operating the computer when the storage device medium is read by the computer to perform the processing described herein. Each such computer program may also be accessed as a service provided by cloud computing infrastructure. The embodiments described herein may also be implemented as a tangible, non-transitory medium, configured with a computer program, where the medium so configured causes a computer to operate in a specific and predefined manner to perform one or more of the processing steps described herein.

The computer program may include one or more modules of a larger program, for example, which provides services related to the design, configuration, and execution of the program. The modules of the program can be implemented as data structures or other organized data conforming to a data model stored in a data repository.

To provide for interaction with a user, embodiments of the subject matter described in this specification can be implemented on a computer having a display device (monitor) for displaying information to the user, and a keyboard and a pointing device, (e.g., a mouse or a trackball) by which the user can provide input to the computer. In addition, a computer can interact with a user by sending documents to and receiving documents from a device that is used by the user (for example, by sending web pages to a web browser on a user's device in response to requests received from the web browser).

Embodiments of the subject matter described in this specification can be implemented in a computing system that includes a back end component (e.g., as a data server), or that includes a middleware component (e.g., an application server), or that includes a front end component (e.g., a user computer having a graphical user interface or a Web browser through which a user can interact with an implementation of the subject matter described in this specification), or any combination of one or more such back end, middleware, or front end components. The components of the system can be interconnected by any form or medium of digital data communication (e.g., a communication network). Examples of communication networks include a local area network (“LAN”), a wide area network (“WAN”), an inter-network (e.g., the Internet), and peer-to-peer networks (e.g., ad hoc peer-to-peer networks).

The computing system can include clients and servers. A client and server are generally remote from each other and typically interact through a communication network. The relationship of client and server arises by virtue of computer programs running on the respective computers and having a client-server relationship to each other. In some embodiments, a server transmits data (e.g., an HTML page) to a client device (e.g., for purposes of displaying data to and receiving user input from a user interacting with the user device). Data generated at the client device (e.g., a result of the user interaction) can be received from the client device at the server.

While this specification contains many specific implementation details, these should not be construed as limitations on the scope of any inventions or of what may be claimed, but rather as descriptions of features specific to particular embodiments of particular inventions.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described above should not be understood as requiring such separation in all embodiments, and it should be understood that the described program components and systems can generally be integrated together in a single software product or packaged into multiple software products.

A number of embodiments have been described. Nevertheless, it will be understood that various modifications may be made without departing from the spirit and scope of the techniques described herein. For example, some of the steps described above may be order independent, and thus can be performed in an order different from that described. Accordingly, other embodiments are within the scope of the following claims.

What is claimed is:

1. A system for generating semantically structured three-dimensional scene representations from unstructured multimedia input data, comprising:
an input data receiver configured to receive unstructured, multimedia input data including one or more: images, videos, three-dimensional data, point cloud data, voice recordings, drawings, or scanned assets associated with a physical interior space;
a two dimensional detector configured to receive the unstructured, multimedia input data and to execute computer vision logic on the received unstructured, multimedia input data to detect one or more building materials, one or more damage patterns, one or more architectural elements, and to extract dimensional information;
a three-dimensional reconstruction engine configured to reconstruct a metrically accurate three-dimensional model of the physical interior space from the input data;
a metadata generation engine configured to generate structured metadata from outputs of the two dimensional detector and the three-dimensional reconstruction engine, the structured metadata including one or more quantitative measurements, one or more material classifications, one or more structural damage assessments, dimensional data, and one or more confidence scores; and
a rule-based converter engine configured to process the structured metadata in accordance with a set of externally defined, carrier-specific rules to generate one or more claims estimate reports, the rule-based converter engine comprising an output generation component configured to produce reports, two-dimensional data, three-dimensional data, and supporting documentation formatted according to the carrier-specific rules.

2. The system of claim 1, further comprising:
a rules engine for insurance claims processing comprising:
a rule management module configured to maintain carrier-specific rule sheets defining trigger conditions based on damage location, material types, and damage characteristics;
a lookup module configured to access structured rule sheets containing condition parameters including supercategory classifications, material specifications, room type specifications, application notifiers with conditional logic statements, action matrices with dynamic categories and calculation instructions, and line item specifications with detailed action descriptions; an evaluation engine configured to process complex conditional logic through structured enumeration systems and dynamic string generation, the evaluation engine maintaining extensive material taxonomies and processing damage in relation to specific structural contexts;
a rule selection component configured to generate dynamic evaluation strings through a BaseModel architecture that processes inclusion and exclusion criteria for parent structures, materials, damage subcategories, and room types; and
a rule application component configured to construct complex boolean expressions combining multiple criteria with AND logic operators and execute carrier-specific guidelines based on the generated evaluation strings.

3. The system engine of claim 1, wherein the rule management module maintains tabbed interfaces enabling selection between multiple rule configurations for different damage scenarios including flooring removal, bathroom floor replacement, wood floor replacement, and carpet repair and replacement.

4. The system engine of claim 1, wherein the evaluation engine maintains material taxonomies including acoustic ceiling tiles, brick, carpet, concrete, fabric, gypsum, gypsum popcorn, laminate, marble, stone, tile variations including standard tile, tile_shower, and tile_tub, vinyl, wallpaper, and wood classifications.

5. The system engine of claim 1, wherein the evaluation engine processes damage classifications including carpet_removed, ceiling_material_removed, delamination, deteriorated surfaces, drywall_removed, exposed_insulation, flood_cut damage, flooring_removed, peeling, rot, sagging, saturated materials, seam damage, staining, swelling, wall_material_removed, and wet damage conditions.

6. The system engine of claim 1, wherein the rule selection component generates evaluation strings that process room introspection including specialized surface detection for tile shower surrounds and tile tub surrounds, room size classification for areas measuring 100 square feet or less, 100-200 square feet, 200-300 square feet, and greater than 300 square feet.

7. The system engine of claim 1, wherein the rule application component processes complex rules including “parent_structure in [‘floor’] and material in [‘brick’, ‘carpet’, ‘concrete’, ‘generic’, ‘laminate’, ‘marble’, ‘other’, ‘stone’, ‘tile’, ‘vinyl’, ‘wood’] and subcategory in [‘carpet_removed’, ‘delamination’, ‘deteriorated’, ‘flooring_removed’, ‘peeling’, ‘saturated’, ‘stained’, ‘swelling’, ‘wet’] and room_type in [‘kitchen’]”.

8. The system engine of claim 1, wherein the evaluation engine supports both positive inclusion criteria for elements that must be present and negative exclusion criteria for elements that must not be present, enabling precise rule specification for complex damage scenarios.

9. The system engine of claim 1, wherein the lookup module accesses action matrices defining specific responses based on dynamic categories, selectors, actions, calculations, and line item information, the action matrices including automated formulas and manual calculation triggers.

10. The system engine of claim 1, wherein the rule application component generates evaluation strings that default to “False” when no conditions are specified, ensuring deterministic rule processing across all carrier-specific guideline applications.

11. The system of claim 1, wherein the 2D detector implements an object-oriented architecture utilizing a Room class that encapsulates spatial and damage analysis detectors, the Room class configured to extract spatial measurements from three-dimensional JSON data structures and maintain structured object hierarchies linking damage instances to parent structural elements through unique identifier relationships.

12. The system of claim 11, wherein the 2D detector includes a threshold-based damage classifier utilizing nearly-zero constants for damage boundary detection, proportional damage assessment computing ratios of damaged versus total structural elements, and multi-state damage recognition distinguishing between removed, damaged, and intact structural elements.

13. The system of claim 2, wherein the rule management module implements an evaluation engine that processes complex conditional logic through structured enumeration systems, the evaluation engine maintaining material taxonomies including acoustic ceiling tiles, brick, carpet, concrete, fabric, gypsum, laminate, marble, stone, tile variations, vinyl, wallpaper, and wood classifications.

14. The system of claim 13, wherein the rule management module processes damage in relation to structural contexts including ceiling, floor, and interior wall classifications, applies room-specific logic for bathroom, kitchen, and laundry environments, and evaluates comprehensive damage classifications including carpet removal, ceiling material removal, delamination, deterioration, drywall removal, exposed insulation, flood cuts, flooring removal, peeling, rot, sagging, saturation, seams, staining, swelling, wall material removal, and wet damage conditions.

15. The system of claim 1, wherein the rule-based converter engine generates dynamic evaluation strings through a BaseModel architecture that processes inclusion and exclusion criteria for parent structures, materials, damage subcategories, and room types, constructing complex boolean expressions combining multiple criteria with AND logic operators.

16. The system of claim 1, wherein the three-dimensional reconstruction engine is configured to perform operations comprising:
receiving, by a computing system, a 2D image representing at least a portion of a physical scene;
processing the 2D image using a trained depth estimation model, the depth estimation model comprising a neural network configured to predict, for each pixel in the 2D image, a depth value representing a relative distance of a corresponding portion of the physical scene from a viewpoint associated with the 2D image;
generating a depth map comprising a plurality of depth values corresponding to a plurality of pixels in the 2D image;
constructing a 3D point cloud by projecting each pixel of the 2D image into a 3D coordinate space using its corresponding depth value and intrinsic parameters of a virtual camera model;
generating a 3D surface model based on the 3D point cloud; and
rendering the 3D surface model for display on a user interface.

17. The system of claim 1, wherein the two-dimensional detector is configured to apply rule-based logic to evaluate the presence, absence, and spatial extent of visual features in the unstructured multimedia input data to classify architectural elements as fully damaged, partially damaged, or removed.

18. The system of claim 2, wherein the rule-based logic comprises logical conditions that include: determining whether a damage region overlaps a building material region by more than a predefined threshold; detecting the absence of expected material boundaries within a specified spatial zone; or identifying whether all detected material boundaries intersect one or more damage regions.

19. The system of claim 1, wherein the two-dimensional detector is further configured to assign, for each detected architectural element, a categorical damage classification based on outputs of rule-based classifiers that analyze semantic segmentation masks, damage region overlays, and edge detection features extracted from the multimedia input data.

20. The system of claim 1, further comprising:
a hardware storage device storing computer executable logic representing rules;
wherein the rule-based converter engine is configured to receive an output from the metadata generator and to read the computer executable logic from the hardware storage device;
wherein the rule-based converter engine is further configured to execute the computer executable logic against the output received from the metadata generator to generate a report; and
wherein the rule-based converter engine is further configured to store the report in the hardware storage device for subsequent retrieval.
